(19) United States
(12) Patent Application Publication
(10) Pub. No.: US 2025/0338700 A1
(43) Pub. Date: Oct. 30, 2025

(54) MICRO LED DISPLAY PANEL

(71) Applicant: JADE BIRD DISPLAY (SHANGHAI) LIMITED, SHANGHAI (CN)

(72) Inventors: Qunchao XU, Shanghai (CN); Weisin TAN, Shanghai (CN); Zhichen GU, Shanghai (CN)

(21) Appl. No.: 19/190,561

(22) Filed: Apr. 25, 2025

(30) Foreign Application Priority Data
Apr. 26, 2024 (WO) PCT/CN2024/090056

(51) Int. Cl. H10H 29/85; H01L 25/075

(52) U.S. Cl. CPC H10H 29/8582; H01L 25/0753; H10H 29/8581

(57) ABSTRACT

A micro LED display panel includes an integrated circuit (IC) backplane; a micro LED array provided on the IC backplane, the IC backplane controlling the micro LED array; and a heat dissipation structure provided on the IC backplane and in contact with edges of the micro LED array.

### CROSS-REFERENCE TO RELATED APPLICATIONS

The present disclosure claims the benefits of priority to PCT Application No. PCT/CN 2024/090056, filed on Apr. 26, 2024, which is incorporated herein by reference in its entirety.

### TECHNICAL FIELD

The present disclosure generally relates to micro LED manufacturing technology, and more particularly, to a micro LED display panel.

### BACKGROUND

Inorganic micro pixel light emitting diodes, also referred to as micro light emitting diodes, micro LEDs, or μ-LEDs, become more important since they are used in various applications including self-emissive micro-displays, visible light communications, and optogenetics. The micro LEDs have higher output performance than conventional LEDs because of better strain relaxation, improved light extraction efficiency, and uniform current spreading. Compared with conventional LEDs, the micro LEDs also exhibit several advantages, such as improved thermal effects, faster response rate, larger working temperature range, higher resolution, wider color gamut, higher contrast, lower power consumption, and operability at higher current density.

Generally, a micro LED display panel includes an array of micro LEDs. Each micro LED may generate heat when emitting light. However, high temperature may impact the performance of the micro LED display panel. Therefore, there is a challenge to improve a heat dissipation effect.

### SUMMARY OF THE DISCLOSURE

Embodiments of the present disclosure provide a micro LED display panel. The micro LED display panel includes an integrated circuit (IC) backplane; a micro LED array provided on the IC backplane, the IC backplane controlling the micro LED array; and a heat dissipation structure provided on the IC backplane and in contact with edges of the micro LED array.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 illustrates a structural diagram showing a top view of an exemplary micro LED display panel, according to some embodiments of the present disclosure.

FIG. 2 illustrates a structural cross-sectional diagram of the micro LED display panel along an A-A′ direction shown in FIG. 1, according to some embodiments of the present disclosure.

FIG. 3 illustrates a structural diagram showing a top view of another exemplary micro LED display panel, according to some embodiments of the present disclosure.

FIG. 4 illustrates a structural cross-sectional diagram of the micro LED display panel along an A-A′ direction shown in FIG. 3, according to some embodiments of the present disclosure.

FIG. 5 illustrates a structural diagram showing a top view of another micro LED display panel, according to some embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the invention. Instead, they are merely examples of apparatuses and methods consistent with aspects related to the invention as recited in the appended claims. Particular aspects of the present disclosure are described in greater detail below. The terms and definitions provided herein control, if in conflict with terms and/or definitions incorporated by reference.

Embodiments of the present disclosure provide a micro LED display panel having improved heat dissipation efficiency.

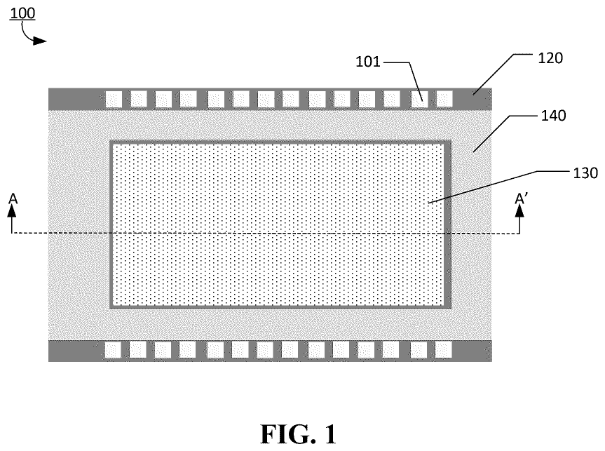

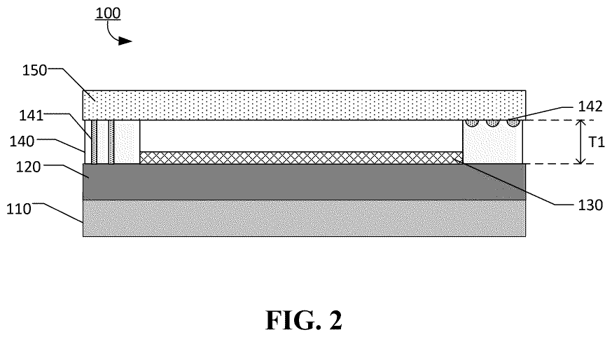

FIG. 1 illustrates a structural diagram showing a top view of an exemplary micro LED display panel 100, according to some embodiments of the present disclosure. FIG. 2 illustrates a structural cross-sectional diagram of the micro LED display panel 100 along an A-A′ direction shown in FIG. 1, according to some embodiments of the present disclosure. Referring to FIG. 1 and FIG. 2 micro LED display panel 100 includes an integrated circuit (IC) backplane 120 and a micro LED array 130 provided on IC backplane 120. IC backplane 120 is configured to control micro LED array 130 to display different images. Micro LED display panel 100 further includes a heat dissipation structure 140 provided on IC backplane 120 and in contact with edges of micro LED array 130. Micro LED array 130 may include a plurality of micro LED structures (not shown) which may generate heat when emitting light. A sidewall of micro LED array 130 is in contact with heat dissipation structure 140, therefore the heat generated by micro LED array 130 can be radiated by heat dissipation structure 140. In some embodiments, heat dissipation structure 140 is provided surrounding micro LED array 130 which can increase the contact surface between heat dissipation structure 140 and micro LED array 130.

In some embodiments, a material of heat dissipation structure 140 is Cu, AIN, SiC, Boron Nitride, diamond or diamond-like carbon, Al, or Invar. Invar is an alloy of nickel and iron, which is also known generically as FeNi36 (64FeNi in US), or named as 4J36. In some embodiments, a thickness T1 of heat dissipation structure 140 is in a range of 1 μm to 1 mm.

In some embodiments, micro LED display panel 100 further includes a cooling plate 110 provided at a bottom of IC backplane 120 for cooling the temperature of IC backplane 120. In some embodiments, a material of cooling plate 110 is a thermal conductive material. For example, the material of the cooling plate is Cu, Al2O3, AlN, SiC, Al, or 4J36 (INVAR).

In some embodiments, an area of cooling plate 110 is greater than an area of IC backplane 120. In some embodiments, an area of cooling plate 110 is the same as an area of IC backplane 120.

In some embodiments, micro LED display panel 100 further includes a cover plate 150 provided above micro LED array 130 and supported by heat dissipation structure 140. In some embodiments, cover plate 150 is transparent. For example, the material of cover plate 150 can be organic glass or inorganic glass.

In some embodiments, micro LED display panel 100 further includes a plurality of input/output (I/O) pads 101 provided at edges of IC backplane 120. The plurality of I/O pads 101 are configured to electrically connect to external circuitry for providing controlling signals to micro LED display panel 100.

Referring to FIG. 2 in some embodiments, when micro LED display panel 100 is provided in a horizontal direction, that is the light emits in a vertical direction. The vertical direction is also a direction perpendicular to the IC backplane 120. Heat dissipation structure 140 further includes or more hollow columns 141 passing through heat dissipation structure 140 in the vertical direction, thereby increasing a heat dissipation area of heat dissipation structure 140.

In some embodiments, heat dissipation structure 140 includes one or more grooves 142 on a surface of heat dissipation structure 140. In some embodiments, the one or more grooves 142 are one or more holes. Therefore, the heat radiation efficiency is further improved.

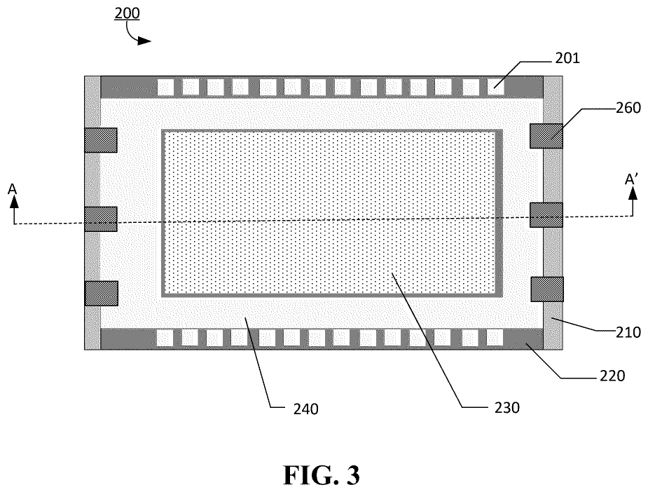

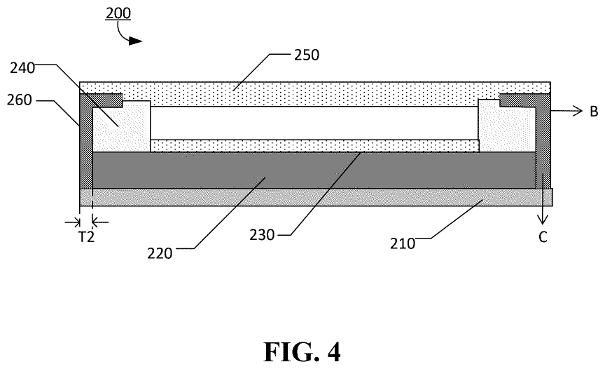

FIG. 3 illustrates a structural diagram showing a top view of an exemplary micro LED display panel 200, according to some embodiments of the present disclosure. FIG. 4 illustrates a structural cross-sectional diagram of the micro LED display panel 200 along an A-A′ direction shown in FIG. 3, according to some embodiments of the present disclosure. Referring to FIG. 3 and FIG. 4, similar to micro LED display panel 100 described in FIG. 1 and FIG. 2 micro LED display panel 200 includes an integrated circuit (IC) backplane 220 and a micro LED array 230 provided on IC backplane 220. IC backplane 220 is configured to control micro LED array 230 to display different images. Micro LED display panel 200 further includes a heat dissipation structure 240 provided on IC backplane 220 and in contact with edges of micro LED array 230. A sidewall of micro LED array 230 is in contact with heat dissipation structure 240. Micro LED display panel 200 further includes a cooling plate 210 provided at a bottom of IC backplane 220 for cooling the temperature of IC backplane 220.

In this example, micro LED display panel 200 further includes one or more enhanced dissipation structures 260 formed on a sidewall of heat dissipation structure 240, which can expedite heat dissipation from the side (illustrated by arrow B). In some embodiments, enhanced dissipation structure 260 is further formed on a sidewall of IC backplane 220, so that heat dissipation of IC backplane 220 can be expedited from the side as well. In some embodiments, enhanced dissipation structure 260 is further in contact with cooling plate 210, and heat dissipation can be further expedited through cooling plate 210 (illustrated by arrow C). In this example, an area of cooling plate 210 is greater than an area of IC backplane 220.

In some embodiments, enhanced dissipation structure 260 is further formed on a portion of a top surface of heat dissipation structure 240. A cover plate 250 is further provided on enhanced dissipation structure 260 and over micro LED array 230. In some embodiments, cover plate 250 is transparent, for example, a material of cover plate 250 can be organic glass or inorganic glass.

As shown in FIG. 3, one or more of enhanced dissipation structures 260 includes one or more strips provided separately on sides of heat dissipation structure 210 different from the sides where input/output (I/O) pads 201 are located. In some embodiments, enhanced dissipation structures 260 can be formed on a whole side of heat dissipation structure 210.

Referring to FIG. 4, in some embodiments, a thickness T2 of enhanced dissipation structures 260 is in a range of 1 μm to 1 mm.

In some embodiments, the one or more enhanced dissipation structures 260 are made of a thermal conductive material. For example, the one or more enhanced dissipation structures 260 includes wires or thermal conductive adhesives. For example, thermal conductive adhesive can be Boron Nitride compound.

Description of other features of micro LED display panel 200 may be found by referring to such features described above with reference to FIG. 1 and FIG. 2 which will not be repeated here.

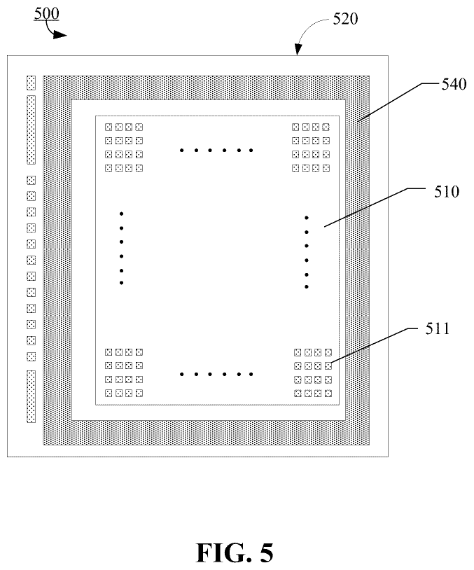

FIG. 5 illustrates a structural diagram showing a top view of a micro LED display panel 500, according to some embodiments of the present disclosure. Referring to FIG. 5, micro LED display panel 500 includes a micro LED array 510 (for example, micro LED array 130, or micro LED array 230) and an IC (integrated circuit) backplane 520 (for example, IC backplane 120 or IC backplane 220). Micro LED array 510 is located on IC backplane 520 to form an image display area of micro LED display panel 500. The rest of the area on IC backplane 520 not covered by micro LED array 510 is formed as a non-functional area. IC backplane 520 is formed at the back surface of micro LED array 510 with a part extending outside of, i.e., not covered by, micro LED array 510. Micro LED array 510 includes a plurality of micro LEDs 511 provided in an array. IC backplane 520 is configured to control the plurality of micro LEDs 511. IC backplane 520 may include a bottom pad array (not shown) corresponding to micro LED array 510. The bottom pad array includes a plurality of bottom pads, and one bottom pad corresponds to one micro LED 511. One micro LED of the plurality of micro LEDs is electrically connected with one bottom pad of the plurality of the bottom pad.

A heat dissipation structure 540 (for example, heat dissipation structure 140 or heat dissipation structure 240) is provided on IC backplane 520 and around micro LED array 510. Heat dissipation structure 540 is also in contact with edges of micro LED array 510 to dissipate heat.

Each micro LED structure herein has a very small volume. The micro LED structure can be applied in a micro LED display panel. The light emitting area of the micro LED display panel, e.g., micro LED display panel 500, is very small, such as 1 mm×1 mm, 3 mm×5 mm, etc. In some embodiments, the light emitting area is the area of micro LED array 510 in micro LED display panel 500. The micro LED display panel includes one or more micro LEDs 511 that form a pixel array in which the micro LEDs of micro LED array 510 are pixels, such as a 1600×1200, 680×480, or 1920×1080-pixel array. The diameter of each micro LED is in the range of about 200 nm to 2 μm. An IC backplane, e.g., IC backplane 520, is formed at the back surface of micro LED array 510 and is electrically connected with micro LED array 510. IC backplane 520 acquires signals such as image data from outside via signal lines to control corresponding micro LEDs 511 to emit light or not.

It is understood by those skilled in the art that the micro LED display panel is not limited by the structure described above, and may include greater or fewer components than those illustrated, or some components may be combined, or a different component may be utilized.

It should be noted that relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the invention disclosed herein. It is intended that the specification and examples be considered as exemplary only, with a true scope and spirit of the invention being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A micro LED display panel, comprising:
an integrated circuit (IC) backplane;
a micro LED array provided on the IC backplane, the IC backplane controlling the micro LED array; and
a heat dissipation structure provided on the IC backplane and in contact with edges of the micro LED array.

2. The micro LED display panel according to claim 1, wherein the heat dissipation structure is provided surrounding the micro LED array.

3. The micro LED display panel according to claim 1, wherein the heat dissipation structure further comprises one or more hollow columns passing through the heat dissipation structure in a vertical direction perpendicular to the IC backplane.

4. The micro LED display panel according to claim 1, wherein the heat dissipation structure further comprises one or more grooves on a surface of the heat dissipation structure.

5. The micro LED display panel according to claim 4, wherein the one or more grooves are one or more holes.

6. The micro LED display panel according to claim 1, further comprising a cooling plate provided at a bottom of the IC backplane.

7. The micro LED display panel according to claim 6, wherein the heat dissipation structure further comprises one or more enhanced dissipation structures formed on a sidewall of the heat dissipation structure.

8. The micro LED display panel according to claim 7, wherein each of the enhanced dissipation structures is further in contact with the cooling plate.

9. The micro LED display panel according to claim 7, wherein each of the one or more enhanced dissipation structures is further formed on a portion of a top surface of the heat dissipation structure.

10. The micro LED display panel according to claim 7, wherein the one or more enhanced dissipation structures are made of a thermal conductive material.

11. The micro LED display panel according to claim 10, wherein the one or more enhanced dissipation structures comprise wires or thermal conductive adhesives.

12. The micro LED display panel according to claim 6, wherein a material of the cooling plate is a thermal conductive material.

13. The micro LED display panel according to claim 12, wherein the material of the cooling plate is Cu, Al2O3, AlN, SiC, Al, or 4J36 (INVAR).

14. The micro LED display panel according to claim 1, wherein a material of the heat dissipation structure is Cu, AlN, SiC, Boron Nitride, diamond or diamond-like carbon, Al, or 4J36 (INVAR).

15. The micro LED display panel according to claim 14, wherein a thickness of the heat dissipation structure is in a range of 1 μm to 1 mm.

16. The micro LED display panel according to claim 1, further comprising a cover plate provided above the micro LED array and supported by the heat dissipation structure.

17. The micro LED display panel according to claim 1, further comprising a plurality of input/output (I/O) pads provided at edges of the IC backplane.
